(19) United States
(12) Patent Application Publication
(10) Pub. No.: US 2025/0192508 A1
(43) Pub. Date: Jun. 12, 2025

(54) LIGHT EMITTING DEVICE

(71) Applicants: NICHIA CORPORATION, Anan-shi (JP); Furukawa Electric Co., Ltd., Tokyo (JP)

(72) Inventor: Masatoshi NAKAGAKI, Komatsushima-shi (JP)

(21) Appl. No.: 18/967,375

(22) Filed: Dec. 3, 2024

(30) Foreign Application Priority Data
Dec. 8, 2023 (JP) 2023-207611

(51) Int. Cl. H01S 5/02253; H01S 5/02255; H01S 5/02325

(52) U.S. Cl. CPC H01S 5/02253; H01S 5/02255; H01S 5/02325

(57) ABSTRACT

A light emitting device includes a base member, a submount, a semiconductor laser element, and a lens. The lens includes a lens portion having an incident surface and a lower surface. When a plane parallel to the lower surface of the lens portion and including a generatrix farthest from the emission end surface is defined as a reference plane, portions of the lens portion, each of which is within a range of a predetermined distance, are symmetrical with respect to the reference plane in a direction normal to the reference plane. A portion of the lens portion extends beyond the predetermined distance from the reference plane in a direction opposite to the lower surface. The lower surface of the lens portion is located at the predetermined distance from the plane. A gap is present between the lower surface of the lens portion and the upper surface of the base member.

### CROSS-REFERENCE TO RELATED APPLICATIONS

This application is based on and claims priority to Japanese Patent Application No. 2023-207611, filed on Dec. 8, 2023, the entire contents of which are incorporated herein by reference.

### BACKGROUND

### 1. Technical Field

The present disclosure relates to a light emitting device.

### 2. Description of Related Art

Light emitting devices including semiconductor laser elements are used in various applications such as processing, projectors, and illumination devices. A typical example of such a light emitting device includes a semiconductor laser element, a submount supporting the semiconductor laser element, and a lens on which light emitted from the semiconductor laser element is incident (see Japanese Patent Publication No. 2000-98190, for example).

### SUMMARY

An object of one embodiment of the present disclosure is to reduce the thickness of a light emitting device.

A light emitting device according to one embodiment of the present disclosure includes a base member, a submount, a semiconductor laser element, and a lens. The submount is disposed on an upper surface of the base member. The semiconductor laser element is disposed on an upper surface of the submount and configured to emit light from an emission end surface. The lens is directly or indirectly fixed to the submount. The lens includes a lens portion having a cylindrical surface, an incident surface, and a lower surface. The incident surface faces the emission end surface of the semiconductor laser element so that the light is to be incident on the incident surface. The lower surface is connected to the incident surface. When a plane that includes a generatrix of the cylindrical surface farthest from the emission end surface in a direction normal to the emission end surface among generatrices of the cylindrical surface and that is parallel to the lower surface of the lens portion is defined as a reference plane, portions of the lens portion, each of which is within a range of a predetermined distance from the reference plane in a direction normal to the reference plane, are symmetrical with respect to the reference plane. The lens portion further includes a portion that extends beyond the predetermined distance from the reference plane in the direction normal to the reference plane toward a direction opposite to the lower surface of the lens portion. The lower surface of the lens portion is located at the predetermined distance from the reference plane. A gap is present between the lower surface of the lens portion and the upper surface of the base member.

### BRIEF DESCRIPTION OF THE DRAWINGS

FIG. 1 is a perspective view of a light emitting device according to a first embodiment;

FIG. 2 is an exploded perspective view of the light emitting device according to the first embodiment;

FIG. 3 is a perspective view of the light emitting device of FIG. 1, from which a frame and a cover are removed;

FIG. 4 is a perspective view illustrating the attachment of a lens according to the present disclosure;

FIG. 5 is a top view of the light emitting device of FIG. 1, from which the cover is removed;

FIG. 6 is a top view of the light emitting device according to the first embodiment;

FIG. 7 is a cross-sectional view of the light emitting device taken through a cross-sectional line VII-VII of FIG. 6;

FIG. 8 is a cross-sectional view of the lens according to the present disclosure;

FIG. 9 is a cross-sectional view of a lens according to a comparative example;

FIG. 10 is an enlarged cross-sectional view of a lens portion and the vicinity of the lens portion of the light emitting device illustrated in FIG. 7; and

FIG. 11 is an enlarged cross-sectional view of a lens portion and the vicinity of the lens portion of a light emitting device according to a modification.

### DETAILED DESCRIPTION

Embodiments of the present invention will be described below with reference to the accompanying drawings. In the following description, terms indicating specific directions and positions (for example, “upper”, “upward”, “lower”, “downward”, and other terms including or related to these terms) are used as necessary. These terms are used to facilitate understanding of the present invention with reference to the drawings, and the technical scope of the present invention is not unduly limited by the meaning of these terms. For example, the term “upper surface” does not necessarily mean that the “upper surface” must face upward at all times. The same reference numerals appearing in a plurality of drawings refer to the same or similar portions or members.

Further, in the present disclosure, the term “polygonal shape” such as a triangular shape and a quadrangular shape encompasses polygonal shapes in which corners of the polygonal shapes are rounded, chamfered, beveled, coved, and the like. Furthermore, the term “polygonal shape” not only encompasses polygonal shapes in which corners (ends of sides) are modified, but also encompasses polygonal shapes in which intermediate portions of the sides are modified. In other words, shapes that are based on polygonal shapes and partially modified are construed as “polygonal shapes” as described in the present disclosure.

The same applies not only to polygonal shapes, but also to terms indicating specific shapes such as trapezoidal shapes, circular shapes, and projections and recesses. The same also applies when referring to sides forming such a shape. In other words, even if a corner or an intermediate portion of a side is modified, the “side” is construed as including the modified portion. In order to distinguish a “polygonal shape” or a “side” without partial modification from a modified shape, such a shape may be expressed with the word “strict” added thereto, for example, a “strict quadrangular shape”.

Further, the following embodiments exemplify light emitting devices and the like to embody the technical ideas of the present invention, and the present invention is not limited to the following description. In addition, unless otherwise specified, the dimensions, materials, shapes, relative arrangements, and the like of components described below are not intended to limit the scope of the present invention thereto, but are described as examples. The contents described in one embodiment can be applied to other embodiments and modifications. The sizes, positional relationships, and the like of members illustrated in the drawings may be exaggerated for a better understanding of the structures. Furthermore, in order to avoid excessive complication of the drawings, a schematic view in which some elements are not illustrated may be used, or an end view illustrating only a cut surface may be used as a cross-sectional view.

### First Embodiment

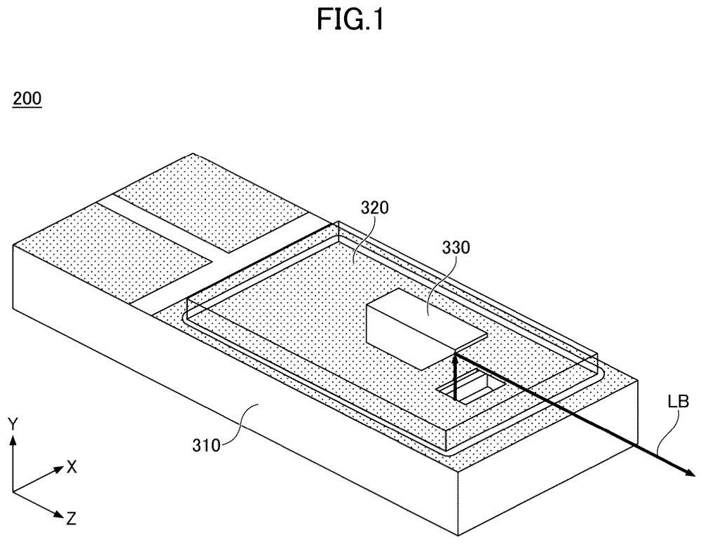

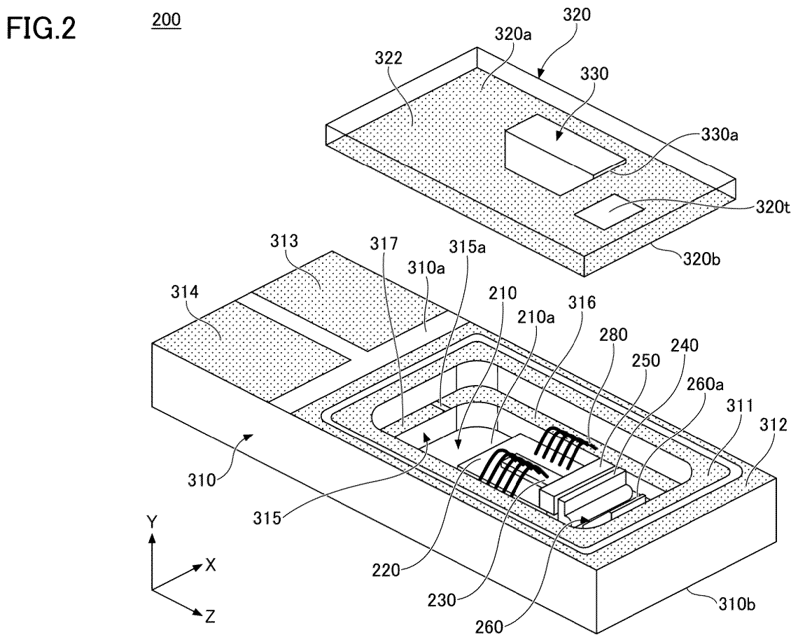

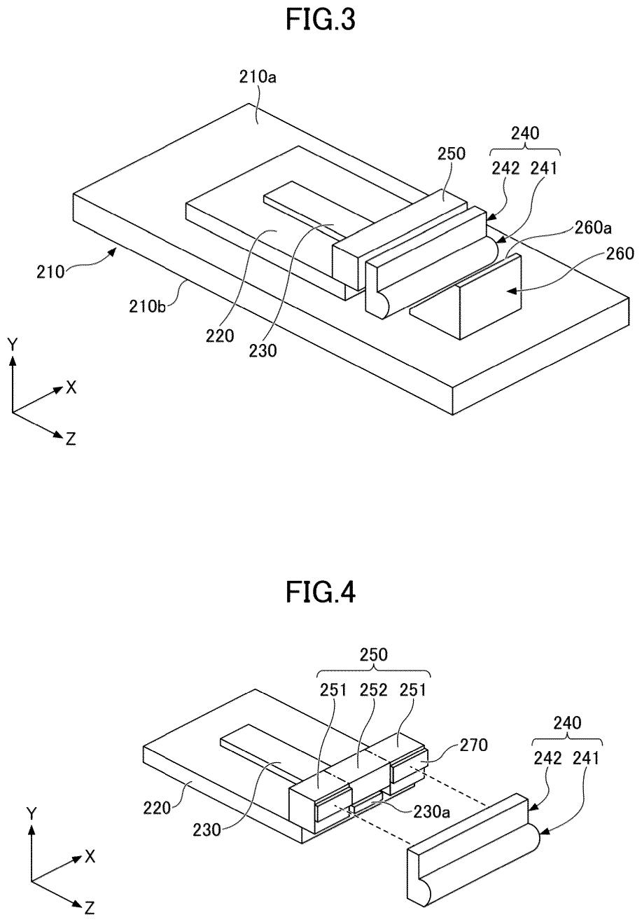

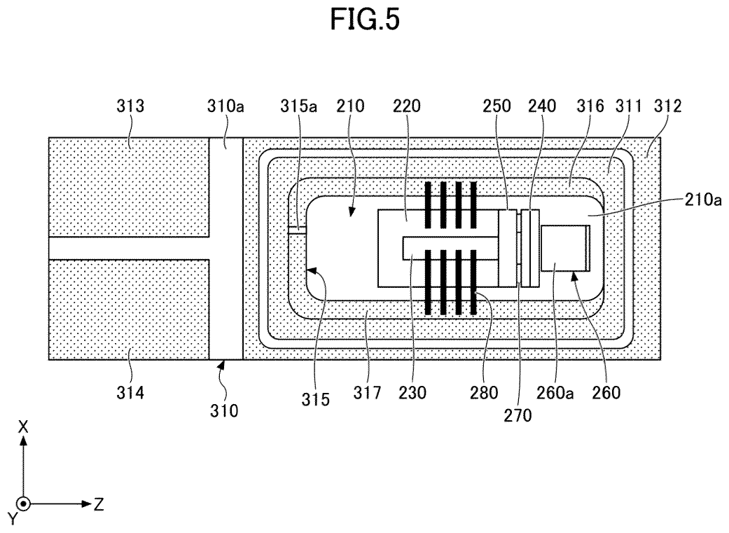

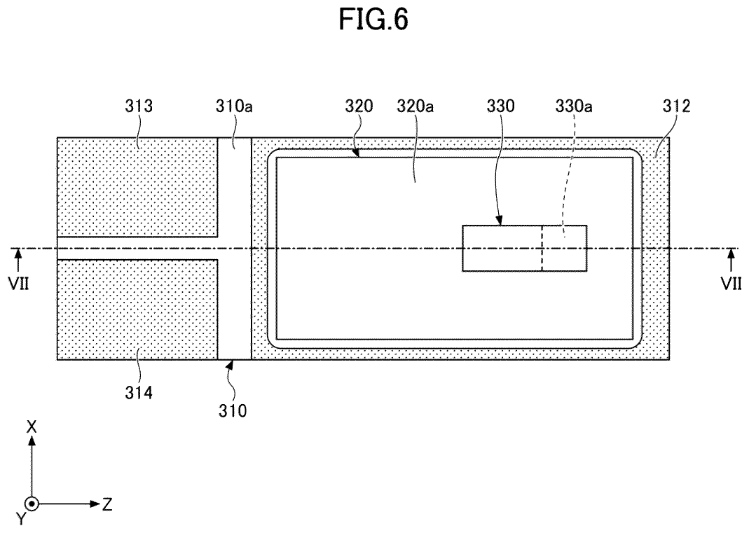

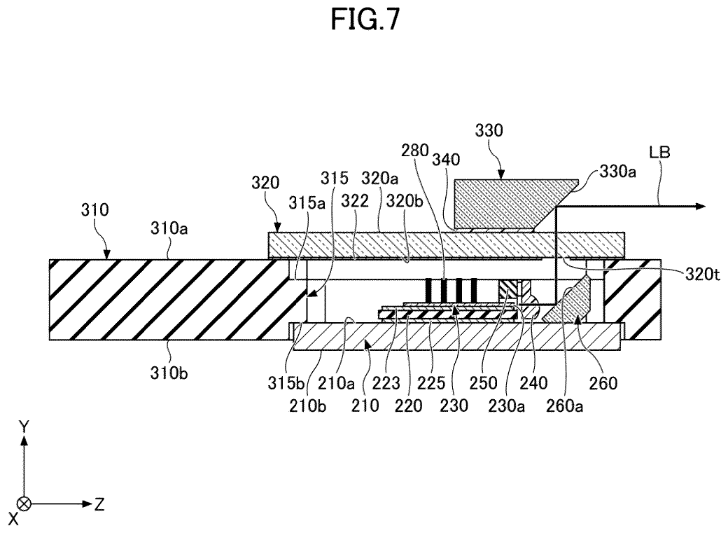

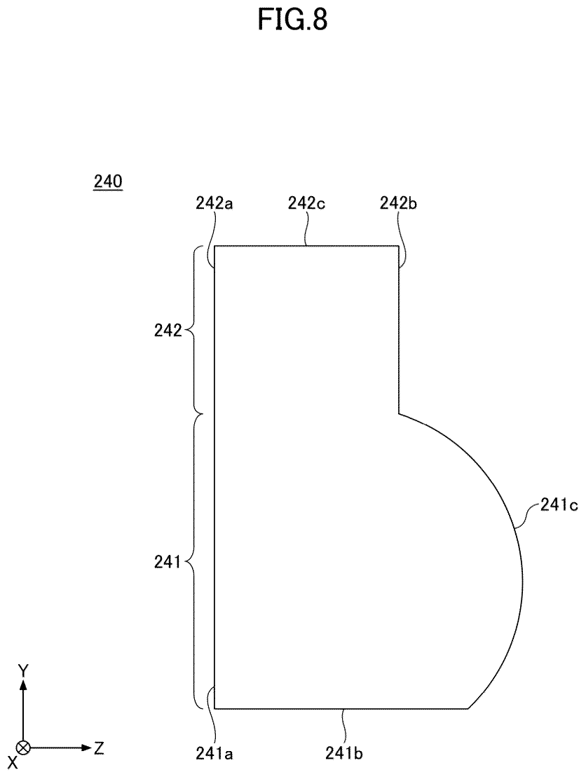

FIG. 1 is a perspective view of a light emitting device according to a first embodiment. FIG. 2 is an exploded perspective view of the light emitting device according to the first embodiment. FIG. 3 is a perspective view of the light emitting device of FIG. 1, from which a frame and a cover are removed. FIG. 4 is a perspective view illustrating the attachment of a lens according to the present disclosure. FIG. 5 is a top view of the light emitting device of FIG. 1, from which the cover is removed. FIG. 6 is a top view of the light emitting device according to the first embodiment. FIG. 7 is a cross-sectional view of the light emitting device taken through a cross-sectional line VII-VII of FIG. 6. FIG. 8 is a side view of the lens according to the present disclosure.

In the drawings, for reference, an X-axis, a Y-axis, and a Z-axis orthogonal to one another are illustrated as necessary. A direction parallel to the X-axis is referred to as an X direction. A direction indicated by an arrow in the X axis direction is referred to as a +X direction, and a direction opposite to the +X direction is referred to as a −X direction. A direction indicated by an arrow in the Y direction is referred to as a +Y direction, and a direction opposite to the +Y direction is referred to as a −Y direction. A direction indicated by an arrow in the Z direction is referred to as a +Z direction, and a direction opposite to the +Z direction is referred to as a −Z direction. However, these directions do not limit the orientation of the light emitting device during use, and the light emitting device may be oriented in any direction.

A light emitting device 200 according to the first embodiment includes a base member 210, a submount 220, a semiconductor laser element 230, and a lens 240 as a minimum configuration. In the example illustrated in FIG. 1 to FIG. 7, the light emitting device 200 further includes a lens support 250, a reflective member 260, a frame 310, a cover 320, and a reflective member 330.

Each component of the light emitting device 200 will be described.

### (Base Member 210)

As illustrated in FIG. 3, the base member 210 has an upper surface 210a and a lower surface 210b. The upper surface 210a is, for example, a flat surface. In the example illustrated in FIG. 3, the lower surface 210b is a flat surface. The upper surface 210a and the lower surface 210b are parallel to each other, for example. As used herein, the term “parallel” includes a tolerance of ±5 degrees. The outer shape of the base member 210 is a rectangular shape in a top view. The rectangular shape may have long sides and short sides. The outer shape of the base member 210 is not necessarily a rectangular shape. Unless specifically stated to exclude a square shape, the term “rectangular shape” may include a square shape.

The base member 210 may be formed of, for example, a metal as a main material. For example, copper, a copper alloy, or the like can be used. The base member 210 may be formed of a main material other than a metal. For example, the base member 210 may be formed of a ceramic. A metal film may be disposed on the upper surface 210a of the base member 210.

### Submount 220

As illustrated in FIG. 3, the submount 220 has, for example, a rectangular parallelepiped shape and has a lower surface, an upper surface, and one or more lateral surfaces. A part of or the entirety of the submount 220 can be formed of at least one selected from the group consisting of, for example, AlN, SiC, alumina, CuW, Cu, a layered structure of Cu/AlN/Cu, and a metal matrix compound (MMC). The MMC contains, for example, at least one selected from the group consisting of Cu, Ag, and Al, and contains diamond. Alternatively, a part of or the entirety of the submount 220 may be formed of any other common material.

The thermal conductivity of the submount 220 can be, for example, 10 (W/m·K) or more and 2,500 (W/m·K) or less. With such thermal conductivity, the submount 220 can efficiently transfer heat generated from the semiconductor laser element 230 to the base member 210 during driving. The thermal expansion coefficient of the submount 220 can be, for example, 2×10⁻⁶ (1/K) or more and 2×10⁻⁵ (1/K) or less. Such a thermal expansion coefficient allows for reducing the possibility that the submount 220 is deformed by heat applied when the semiconductor laser element 230 is bonded onto the submount 220 with a bonding material. The size of the submount 220 in the X direction is, for example, 1 mm or more and 3 mm or less, the size of the submount 220 in the Y direction is, for example, 0.1 mm or more and 0.5 mm or less, and the size of the submount 220 in the Z direction is, for example, 1 mm or more and 6 mm or less.

Metal films having a thickness of, for example, 0.5 μm or more and 10 μm or less may be formed on the upper surface and the lower surface of the submount 220 by, for example, plating. In the example of FIG. 1 to FIG. 7, a metal film 223 is formed on the upper surface of the submount 220, and a metal film 225 is formed on the lower surface of the submount 220. The metal film 223 is useful when the submount 220 and the semiconductor laser element 230 are bonded to each other with a bonding material and when electric power is supplied to the semiconductor laser element 230. The metal film 225 is useful when the submount 220 and the upper surface 210a of the base member 210 are bonded to each other with a bonding material. With the metal film 223 and the metal film 225, the heat dissipation of the submount 220 can be improved.

### Semiconductor Laser Element 230

In the illustrated example, the light emitting device 200 includes one semiconductor laser element 230. The light emitting device 200 may include a plurality of semiconductor laser elements. The semiconductor laser element 230 has, for example, a rectangular outer shape in a top view. A lateral surface meeting one of the two short sides of the rectangle is an emission end surface 230a through which light is emitted from the semiconductor laser element 230. Further, the area of each of the upper surface and the lower surface of the semiconductor laser element 230 is larger than the area of the emission end surface 230a.

A metal film may be provided at the upper surface of the semiconductor laser element 230. This metal film is provided with, for example, wiring or the like for electrical conduction with other members.

Light (laser light) emitted from the semiconductor laser element 230 diverges and forms an elliptical far field pattern (hereinafter referred to as an “FFP”) on a plane parallel to the emission end surface 230a. The FFP indicates the shape and the light intensity distribution of the emitted light at a position away from the emission end surface.

In the elliptical light emitted from the semiconductor laser element 230, the direction passing through the major axis of the elliptical shape is defined as the fast axis direction of the FFP, and the direction passing through the minor axis of the elliptical shape is defined as the slow axis direction of the FFP. The fast axis direction of the FFP in the semiconductor laser element 230 can correspond to the stacking direction in which a plurality of semiconductor layers including an active layer of the semiconductor laser element 230 are stacked.

In the present specification, light having an intensity of 1/e² or more of the peak intensity within the light intensity distribution of the FFP of the semiconductor laser element 230 will be referred to as main light. Further, an angle corresponding to an intensity of 1/e² in the light intensity distribution will be referred to as an angle of divergence. The angle of divergence in the fast-axis direction of the FFP is larger than the angle of divergence in the slow-axis direction of the FFP. Herein, e is the base of the natural logarithm.

Further, light passing through the center of the elliptical shape of the FFP, in other words, light with the peak intensity in the light intensity distribution of the FFP, will be referred to as light traveling along the optical axis or light passing along the optical axis. An optical path of light traveling through the center of the elliptical shape of the FFP will be referred to as the optical axis of the light.

A semiconductor laser element that emits blue light can be used as the semiconductor laser element 230. The “semiconductor laser element that emits blue light” refers to a semiconductor laser element that emits light having an emission peak wavelength in a range of 405 nm to 494 nm. As the semiconductor laser element 230, it is preferable to use a semiconductor laser element that emits light having a peak wavelength in a range of 430 nm to 480 nm. Examples of the semiconductor laser element 230 include a semiconductor laser element including a nitride semiconductor. As the nitride semiconductor, for example, GaN, InGaN, AlGaN, or AlInGaN can be used.

The emission peak of light emitted from the semiconductor laser element 230 is not necessarily limited to the above. For example, light emitted from the semiconductor laser element 230 may be visible light having wavelengths outside the above-described wavelength range of blue light, such as green light, red light, or violet light, or may be ultraviolet light or infrared light.

### Lens 240

As illustrated in FIG. 8, the lens 240 includes a lens portion 241 as a minimum configuration. The lens portion 241 includes an incident surface 241a on which light emitted from the semiconductor laser element 230 is incident, a lower surface 241b connected to the incident surface 241a, and a cylindrical surface 241c from which the light incident on the incident surface 241a exits. The cylindrical surface 241c is connected to the lower surface 241b.

The incident surface 241a and the lower surface 241b are, for example, flat surfaces. The incident surface 241a is, for example, perpendicular to the lower surface 241b. The cylindrical surface 241c is a convex curved surface (a surface of a section of a cylinder) functioning as a lens, and has a curvature in the YZ plane. The lens portion 241 may be, for example, a cylindrical lens having a uniform cross-sectional shape in the X direction.

In the example illustrated in FIG. 8, the lens 240 further includes an extension portion 242 extending from the lens portion 241 to the side opposite to the lower surface 241b. Including the extension portion 242 allows the lens 240 to be easily bonded to the lens support 250. The extension portion 242 includes a first surface 242a continuous with the incident surface 241a and coplanar with the incident surface 241a, a second surface 242b continuous with the cylindrical surface 241c, and a third surface 242c connecting the first surface 242a and the second surface 242b. In the example illustrated in FIG. 8, the second surface 242b is a flat surface and is parallel to the first surface 242a. Further, the third surface 242c is a flat surface and is parallel to the lower surface 241b of the lens portion 241. The second surface 242b and the third surface 242c are not limited to the above-described configuration.

The lens 240 can be formed of at least one light-transmissive material selected from the group consisting of glass, silicon, quartz, synthetic quartz, sapphire, and a transparent ceramic, for example. The lens portion 241 and the extension portion 242 may be integrally formed or may be separate members that are bonded together. From the viewpoint of improving the mechanical strength of the lens 240, the lens portion 241 and the extension portion 242 are preferably integrally formed.

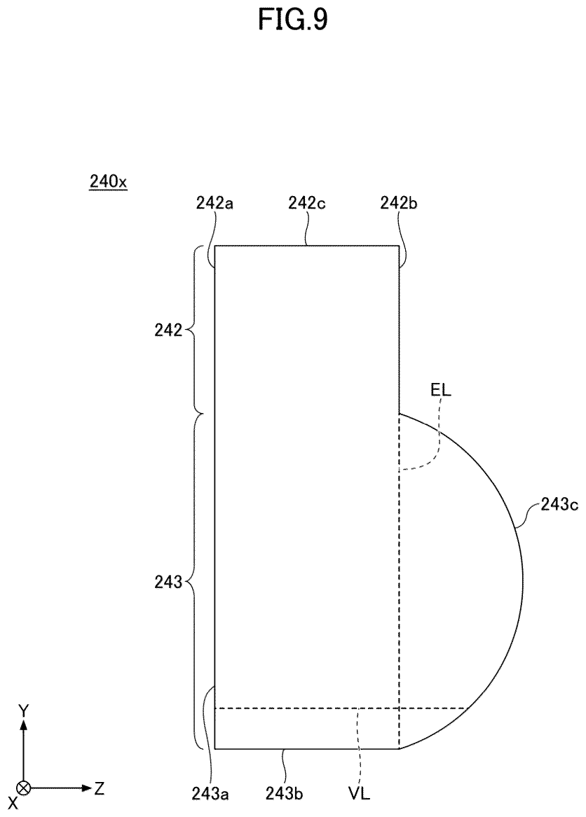

FIG. 9 is a cross-sectional view of a lens according to a comparative example. As illustrated in FIG. 9, a lens 240x according to the comparative example differs from the lens 240 in that the lens portion 241 is replaced with a lens portion 243. An extension portion 242 of the lens 240x is the same as the extension portion 242 of the lens 240.

The lens portion 243 has an incident surface 243a on which light emitted from the semiconductor laser element 230 is incident, a lower surface 243b connected to the incident surface 243a, and a cylindrical surface 243c from which the light incident on the incident surface 243a exits. The cylindrical surface 243c is connected to the lower surface 243b.

Similar to the incident surface 241a, the incident surface 243a is a flat surface. When the position of the third surface 242c of the extension portion 242 of the lens 240x in the Y direction is aligned with the position of the third surface 242c of the extension portion 242 of the lens 240 in the Y direction, the lower end of the incident surface 243a is located on the −Y side relative to the lower end of the incident surface 241a. The cylindrical surface 243c is a convex curved surface functioning as a lens, and has the same curvature as the curvature of the cylindrical surface 241c in the YZ plane. In addition, when the position of the third surface 242c of the extension portion 242 of the lens 240x in the Y direction is aligned with the position of the third surface 242c of the extension portion 242 of the lens 240 in the Y direction, the lower end of the cylindrical surface 243c is located on the −Y side relative to the lower end of the cylindrical surface 241c. The lower end of the cylindrical surface 243c is located on, for example, an extension line EL of the second surface 242b of the extension portion 242 in a cross-sectional view.

An imaginary line VL indicates the position of the lower surface 241b of the lens 240. The shape of a portion located on the +Y side of the lens 240x relative to the imaginary line VL is the same as the shape of the lens 240. The lens 240x has a shape in which a portion located on the −Y side of the lens portion 243 relative to the imaginary line VL is increased as compared to the lens 240. In other words, the lens 240 has a shape in which a portion corresponding to a portion located on the −Y side of the lens 240x relative to the imaginary line VL is removed. The length of the lens 240 in the Y direction is smaller than the length of the lens 240x in the Y direction.

### Lens Support 250

As illustrated in FIG. 4, the lens support 250 includes two columnar portions 251 and a connection portion 252. The connection portion 252 is located between the two columnar portions 251 and connects the two columnar portions 251. The lens support 250 may be formed of, for example, a ceramic selected from the group consisting of AlN, SiN, SiC, and alumina, or may be formed of at least one alloy selected from the group consisting of Kovar and CuW. The lens support 250 may be formed of, for example, Si.

### Reflective Member 260

The reflective member 260 has a lower surface, a reflective surface 260a that reflects light from the cylindrical surface 241c of the lens portion 241, and a plurality of lateral surfaces meeting the reflective surface 260a and the lower surface. In the illustrated light emitting device 200, the lower surface, the reflective surface 260a, and the plurality of lateral surfaces are flat surfaces. The reflective member 260 may have a triangular shape in a side view. In particular, the reflective member 260 may have a triangular shape with chamfered corners in a side view.

The plurality of lateral surfaces include two lateral surfaces opposite to each other with the reflective surface 260a located therebetween. Further, the plurality of lateral surfaces include one lateral surface meeting the two lateral surfaces opposite to each other with the reflective surface 260a located therebetween. The two lateral surfaces opposite to each other with the reflective surface 260a located therebetween may have the same area.

In the illustrated light emitting device 200, the reflective surface 260a has a rectangular shape. The reflective surface 260a is inclined with respect to the lower surface of the reflective member 260. The inclination angle of the reflective surface 260a with respect to the lower surface of the reflective member 260 is, for example, 45 degrees; however, the inclination angle of the reflective surface 260a is not limited thereto and may be 30° or more and 60° or less. When a specific inclination angle is described, the specific angle in a product may be with a tolerance of ±5 degrees from the specific angle is allowed for products in consideration of manufacturing accuracy.

The lower surface and the reflective surface 260a may both be a curved surface, or may be a combination of a flat surface and a curved surface. Further, the reflective surface 260a does not necessarily have a rectangular shape as long as the reflective surface 260a can reflect incident light in a desired direction.

Glass, a metal, or the like can be used as a main material forming the outer shape of the reflective member 260. The main material is preferably a heat-resistant material, and, for example, glass such as quartz or BK7 (borosilicate glass), a metal such as aluminum, or Si can be used. Further, the reflective surface 260a may be provided with a metal or a dielectric multilayer film. Examples of the metal include Ag and Al. Examples of the material of the dielectric multilayer film include Ta₂O₅/SiO₂, TiO₂/SiO₂, and Nb₂O₅/SiO₂.

### Wiring 280

Wiring 280 is composed of a conductor having a linear shape with both ends serving as bonding portions. In other words, the wiring 280 has, at both ends of the linear-shaped portion, bonding portions to be bonded to other components. The wiring 280 is used for electrical connection between two components. As the wiring 280, for example, a metal wire can be used. Examples of the metal include gold, aluminum, silver, copper, and tungsten.

### Frame 310

The frame 310 has an upper surface 310a, a lower surface 310b, one or more inner lateral surfaces, and one or more outer lateral surfaces. The frame 310 has, for example, a rectangular frame shape in a top view. The one or more inner lateral surfaces of the frame 310 meet the upper surface 310a and extend downward from the upper surface 310a. The one or more outer lateral surfaces of the frame 310 meet the upper surface 310a and the lower surface 310b of the frame 310.

A metal film 311 and a metal film 312 that surrounds the metal film 311 and is spaced apart from the metal film 311 can be provided on the upper surface 310a of the frame 310. The metal films 311 and 312 have, for example, substantially rectangular frame shapes. The metal films 311 and 312 surround the submount 220, the semiconductor laser element 230, the lens 240, the lens support 250, and the reflective member 260 in a top view. The metal film 311 can be used when the frame 310 is bonded to the cover 320 via, for example, a metal adhesive. With the metal film 312, the metal adhesive for bonding the cover 320 is less likely to flow out beyond the metal film 312.

Metal films 313 and 314 electrically insulated from each other can be further provided on the upper surface 310a of the frame 310. The metal films 313 and 314 are located on the −Z side of the frame 310 relative to the metal film 312. For example, the metal film 313 and the metal film 314 are spaced apart from each other and are aligned in the X direction. The metal films 313 and 314 have, for example, rectangular shapes having substantially the same area. For example, Ni/Au, Ti/Pt/Au, or the like can be used for the metal films 311, 312, 313, and 314.

The frame 310 may further include a stepped portion 315 having an upper surface 315a located above the upper surface 210a of the base member 210 and below the upper surface 310a of the frame 310. The stepped portion 315 further has inner lateral surfaces meeting the upper surface 315a and extending downward. The upper surface 315a meets the one or more inner lateral surfaces of the frame 310. The upper surface 315a can be parallel to the upper surface 210a of the base member 210, for example. The inner lateral surfaces of the stepped portion 315 meet, for example, the upper surface 210a of the base member 210. The inner lateral surfaces of the stepped portion 315 are connected to, for example, the inner lateral surfaces of the frame 310. The stepped portion 315 can be provided along some or all of the inner lateral surfaces of the frame 310 in a top view.

Metal films 316 and 317 may be disposed on the upper surface 315a of the stepped portion 315. A material similar to or the same as that of the metal film 311 can be used for the metal films 316 and 317. The metal film 316 can be electrically connected to the metal film 313 through, for example, a via-wiring. The metal film 317 can be electrically connected to the metal film 314 through, for example, a via-wiring.

The stepped portion 315 can further have a lower surface 315b meeting the inner lateral surfaces of the stepped portion 315. The lower surface 315b may be a flat surface parallel to the upper surface 315a. The lower surface 315b is located above the lower surface 310b of the frame 310. The lower surface 315b of the stepped portion 315 is bonded to the upper surface 210a of the base member 210. In the illustrated example, the frame 310 further has lateral surfaces meeting the lower surface 315b and extending downward. The lateral surfaces meet the lower surface 310b of the frame 310.

The frame 310 can be formed of, for example, a material different from that of the base member 210 as a main material. Examples of the material forming the frame 310 include a ceramic. For example, as the ceramic, aluminum nitride, silicon nitride, aluminum oxide, or silicon carbide can be used.

### Cover 320

The cover 320 has an upper surface 320a, a lower surface 320b, and one or more lateral surfaces meeting the upper surface 320a and the lower surface 320b. The one or more lateral surfaces connect an outer edge of the upper surface 320a and an outer edge of the lower surface 320b. The cover 320 has, for example, a rectangular parallelepiped shape or a cube shape. In this case, both the upper surface 320a and the lower surface 320b of the cover 320 have a rectangular shape, and the cover 320 has four lateral surfaces each having a rectangular shape.

The cover 320 is not limited to a rectangular parallelepiped shape or a cube shape. That is, the cover 320 is not limited to a rectangular shape in a top view, and can have any shape such as a circular shape, an elliptical shape, or a polygonal shape.

The cover 320 has a light transmitting region 320t that transmits light. The light transmitting region 320t constitutes at least a portion of the upper surface 320a and a portion of the lower surface 320b. The shape of the light transmitting region 320t is, for example, a rectangular shape, but is not limited thereto. For example, the light transmitting region 320t of the cover 320 can be formed by using sapphire as a main material. Sapphire is a material with relatively high transmittance and relatively high strength. Other than sapphire, a light-transmissive material such as quartz, silicon carbide, or glass may be used as the main material of the light transmitting region 320t of the cover 320. A portion of the cover 320 other than light transmitting region 320t may be formed of the same material as that of the light transmitting region 320t and may be formed integrally with the light transmitting region 320t. The light transmitting region 320t preferably transmits 70% or more of laser light LB.

In the illustrated example, the cover 320 includes a light shielding film 322 around the light transmitting region 320t of the lower surface 320b. The shape of the light transmitting region 320t is a rectangular shape, but is not limited thereto. The shape of the light transmitting region 320t may be, for example, a circular shape or an elliptical shape.

The light shielding film 322 allows for reducing the possibility that stray light other than laser light generated inside the light emitting device 200 leaks to the outside of the light emitting device 200. The light shielding film 322 allows for further reducing the possibility that ultraviolet light or visible light reaches the semiconductor laser element 230 when a resin layer 340 illustrated in FIG. 7 is cured by irradiation with ultraviolet light or visible light and thus is formed. The light shielding film 322 allows for further reducing the possibility that light (hereinafter referred to as return light) that has returned to the light emitting device 200 due to diffuse reflection and the like, of the laser light LB emitted to the outside of the light emitting device 200, reaches the semiconductor laser element 230. If the semiconductor laser element 230 can be inhibited from being irradiated with ultraviolet light, visible light, or return light is, the semiconductor laser element 230 is less likely to be damaged.

The light shielding film 322 is preferably provided on the entire region of the lower surface 320b other than the light transmitting region 320t. The light shielding film 322 provided in this manner allows for further reducing the possibility that stray light as described above leaks to the outside of the light emitting device 200, and the possibility that ultraviolet light or visible light or return light described above reaches the semiconductor laser element 230. The light shielding film 322 can be formed of, for example, a material similar to or the same as that of the metal film 311.

### Reflective Member 330

The reflective member 330 has a lower surface, a reflective surface 330a that reflects light reflected by the reflective member 260, and a plurality of lateral surfaces meeting the reflective surface 330a and the lower surface. In the illustrated light emitting device 200, each of the lower surface, the reflective surface 330a, and the plurality of lateral surfaces is a flat surface.

The plurality of lateral surfaces include two lateral surfaces opposite to each other on both sides of the reflective surface 330a. In addition, the plurality of lateral surfaces include one lateral surface meeting the two opposite lateral surfaces on both sides of the reflective surface 330a. The two opposite lateral surfaces on both sides of the reflective surface 330a may have the same area.

In the illustrated light emitting device 200, the reflective surface 330a has a rectangular shape. The reflective surface 330a is inclined with respect to the lower surface of the reflective member 330. The inclination angle of the reflective surface 330a with respect to the lower surface of the reflective member 330 is, for example, 45 degrees; however, the inclination angle of the reflective surface 330a with respect to the lower surface is not limited thereto, and may be 30° or more and 60° or less.

The lower surface and the reflective surface 330a may both be a curved surface, or may be a combination of a flat surface and a curved surface. The reflective surface 330a does not necessarily have a rectangular shape as long as the reflective surface 330a can reflect incident light in a desired direction.

As a main material forming the outer shape of the reflective member 330, a material similar to or the same as that of the reflective member 260 can be used. Further, the reflective surface 330a can be formed by using, for example, a material similar to or the same as that of the reflective member 260.

### Light Emitting Device 200

Next, the light emitting device 200 will be described.

The submount 220 is disposed on the upper surface 210a of the base member 210. More specifically, the lower surface of the submount 220 on which the metal film 225 is provided is bonded to the upper surface 210a of the base member 210 via a metal adhesive. The semiconductor laser element 230 is directly or indirectly disposed on the upper surface of the submount 220 disposed on the upper surface 210a of the base member 210. For example, the semiconductor laser element 230 is bonded to the metal film 223 provided on the upper surface of the submount 220 via, for example, a metal adhesive. Examples of the metal adhesives used for bonding include AuSn.

The semiconductor laser element 230 is disposed such that the emission end surface 230a is oriented in a direction that is the same as a direction in which one lateral surface of the submount 220 is oriented. Further, the emission end surface 230a of the semiconductor laser element 230 can be parallel to or perpendicular to, for example, one inner lateral surface or one outer lateral surface of the frame 310. The semiconductor laser element 230 emits light to travel in the Z direction. The light emitted from the semiconductor laser element 230 is, for example, blue light. The light emitted from the semiconductor laser element 230 is not limited to the blue light.

The semiconductor laser element 230 is electrically connected to the metal film 317, disposed on the upper surface 315a of the stepped portion 315, via the wiring 280. One end of the wiring 280 is bonded to the metal film provided on the upper surface of the semiconductor laser element 230. For example, the light emitting device 200 further includes a plurality of wirings 280. The plurality of wirings 280 include a wiring 280 having one end connected to the metal film 316 provided on the upper surface 315a of the stepped portion 315 and the other end connected to the metal film provided on the submount 220. With such a connection, when a voltage is applied between the metal films 313 and 314 provided on the upper surface 310a of the frame 310, power is supplied to the semiconductor laser element 230.

The lens 240 is directly or indirectly fixed to the submount 220. In the example of FIG. 1 to FIG. 7, the lens 240 is fixed to the lens support 250 provided on the upper surface of the submount 220. The lens support 250 is provided on the upper surface of the submount 220 and supports the lens 240. The first surface 242a of the extension portion 242 is bonded to the lens support 250, and thus the lens 240 is supported by the lens support 250. Thus, with the lens support 250, the lens 240 can be easily fixed to the submount 220.

As illustrated in FIG. 4, the two columnar portions 251 of the lens support 250 are located on both sides of the semiconductor laser element 230, and the connection portion 252 is located above the emission end surface 230a of the semiconductor laser element 230. The lens support 250 is located so as to straddle the semiconductor laser element 230, and does not prevent the laser light emitted from the semiconductor laser element 230 from being incident on the lens 240.

The lens 240 is supported by the lens support 250 such that the incident surface 241a of the lens portion 241 faces the emission end surface 230a of the semiconductor laser element 230. Specifically, the first surface 242a of the extension portion 242 is bonded to the end surfaces of the two columnar portions 251 of the lens support 250 via bonding materials 270. With such a configuration, the bonding materials 270 can be located away from the incident surface 241a, and thus the possibility that an organic substance and the like generated by the bonding materials 270 contaminate the incident surface 241a due to optical dust collection can be reduced. Examples of the bonding materials 270 include AuSn and Au paste.

As illustrated in FIG. 4, it is preferable that the bonding materials 270 are provided only on the end surfaces of the columnar portions 251 of the lens support 250 and are not provided on the end surface of the connection portion 252. Accordingly, the bonding materials 270 can be provided away from a region of the incident surface 241a of the lens 240 on which the laser light is incident. As a result, a portion of the bonding materials 270 is less likely to adhere to the incident surface 241a of the lens 240, and thus the possibility that the lens 240 is contaminated or a beam pattern is disturbed by a portion of the bonding materials 270 adhering to the incident surface 241a can be reduced.

Metal films may be formed on the first surface 242a of the extension portion 242 of the lens 240 and the end surfaces of the columnar portions 251 of the lens support 250, and these metal films may be bonded to each other via, for example, a metal adhesive. Examples of the metal adhesive used for the bonding include AuSn and Au paste. Further, active alignment may be performed when the metal films are bonded to each other. The active alignment is, for example, to adjust, in a state in which the semiconductor laser element 230 emits the laser light LB, the position and the orientation of the lens 240 such that the main light emitted from the semiconductor laser element 230 enters the cylindrical surface 241c of the lens 240.

The focal point of the lens portion 241 substantially coincides with the center of a light emission point of the emission end surface 230a of the semiconductor laser element 230. The lens portion 241 collimates the laser light LB emitted in the +Z direction from the emission end surface 230a of the semiconductor laser element 230 in the YZ plane.

The reflective member 260 is disposed on the upper surface 210a of the base member 210. For example, the reflective member 260 is disposed on a metal film provided directly under the reflective member 260. The lower surface of the reflective member 260 is located below the lower surface 241b of the lens portion 241. Further, it is preferable that the lowermost portion of the reflective surface 260a is located below the lower surface 241b of the lens portion 241. With this configuration, a larger amount of light exiting from the cylindrical surface 241c can easily reach the reflective surface 260a. A metal film is provided on the lower surface of the reflective member 260 includes a metal film at the lower surface thereof, and the metal film and the upper surface 210a of the base member 210 are bonded to each other via, for example, a metal adhesive. Examples the metal adhesive used for the bonding include AuSn and Au paste.

The reflective member 260 is disposed, on the upper surface 210a of the base member 210, at a lateral side of the lens portion 241. In the Z direction, the reflective member 260 is disposed at a side opposite to a side at which the semiconductor laser element 230 is located, with the lens portion 241 located therebetween. The reflective surface 260a of the reflective member 260 faces the cylindrical surface 241c of the lens portion 241. The reflective surface 260a reflects the laser light LB, emitted from the emitting end surface 230a of the semiconductor laser element 230 and passing through the lens portion 241, upward (in the +Y direction).

An outer peripheral portion of the upper surface of the base member 210 is bonded to the lower surface 315b of the stepped portion 315 of the frame 310. In a top view, the submount 220, the semiconductor laser element 230, the lens 240, the lens support 250, and the reflective member 260 are surrounded by the frame 310.

The cover 320 is disposed on the upper surface 310a of the frame 310. Specifically, the cover 320 is supported by the upper surface 310a of the frame 310, and is disposed above the semiconductor laser element 230 surrounded by the frame 310. An outer peripheral portion of the lower surface 320b of the cover 320 is bonded to, for example, the upper surface 310a of the frame 310. For example, a metal film disposed on the outer peripheral portion of the lower surface 310b of the cover 320 and the metal film 311 provided on the upper surface 310a of the frame 310 are bonded to each other via AuSn or the like.

By bonding the lower surface 320b of the cover 320 to the upper surface 310a of the frame 310, a sealed space in which the semiconductor laser element 230 is disposed is formed by the base member 210, the frame 310, and the cover 320. The sealed space may be formed to be airtight. The sealed space formed to be airtight can reduce the possibility of collection of dust such as organic substances on the emission end surface 230a of the semiconductor laser element 230.

The lower surface of the reflective member 330 is fixed to the upper surface 320a of the cover 320 with the resin layer 340 located therebetween. The reflective surface 330a of the reflective member 330 at least partially overlaps the light transmitting region 320t of the cover 320 and the reflective surface 260a of the reflective member 260 in a top view. The resin constituting the resin layer 340 can be, for example, a thermosetting resin that is cured by being heated or a photocurable resin that is cured by being irradiated with ultraviolet light or visible light.

The laser light LB reflected in the +Y direction by the reflective surface 260a of the reflective member 260 is transmitted through the light transmitting region 320t of the cover 320 and reaches the reflective surface 330a of the reflective member 330. The laser light LB that has reached the reflective surface 330a of the reflective member 330 is reflected by the reflective surface 330a, thereby the traveling direction of the laser light LB is changed to the +Z direction.

When the resin layer 340 is formed, active alignment may be performed before the resin is cured. That is, in the case of forming the resin layer 340, in a state in which the semiconductor laser element 230 emits the laser light LB, the position and the orientation of the reflective member 330 may be adjusted such that the traveling direction of the laser light LB is changed to the +Z direction by the reflective surface 330a, and subsequently, the resin may be cured.

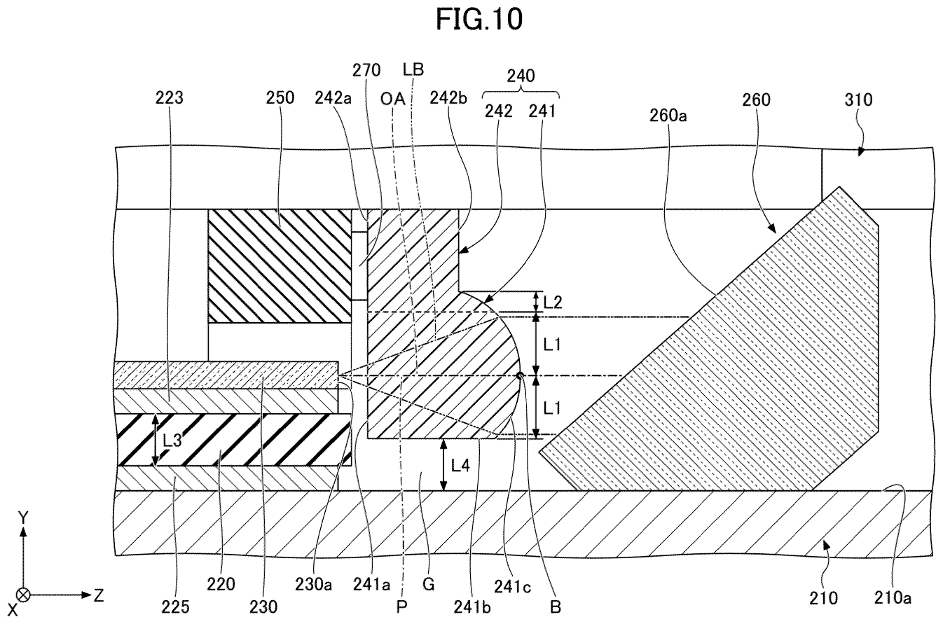

By reducing the thickness of the submount 220, the heat dissipation of the light emitting device 200 can be improved, and also the thickness of the light emitting device 200 can be reduced. However, for example, if the lens 240x illustrated in FIG. 9 is used and the thickness of the submount 220 is reduced, the lower surface 243b of the lens portion 243 would come into contact the upper surface 210a of the base member 210 and the lens 240x would fall off when the lens 240x is mounted in a manufacturing process of the light emitting device 200. In contrast, as described above, the lens 240 illustrated in FIG. 8 has a shape in which a portion corresponding a portion located on the −Y side of the lens 240x relative to the imaginary line VL is removed, and the length of the lens 240 in the Y direction is smaller than the length of the lens 240x in the Y direction. Therefore, in the case of using the lens 240 illustrated in FIG. 8, even if the thickness of the submount 220 is reduced, the possibility that the lower surface 241b of the lens portion 241 comes into contact with the upper surface 210a of the base member 210 when the lens 240 is mounted in a manufacturing process of the light emitting device 200 can be reduced. That is, by using the lens 240 illustrated in FIG. 8, the thickness of the submount 220 can be reduced while reducing the possibility that the lens 240 comes into contact with the upper surface 210a of the base member 210. Thus, the heat dissipation of the light emitting device 200 can be improved and also the thickness of the light emitting device 200 can be reduced. A specific example will be described with reference to FIG. 10.

FIG. 10 is an enlarged cross-sectional view of the lens portion and the vicinity of the lens portion of the light emitting device illustrated in FIG. 7. In FIG. 10, B indicates a generatrix farthest from the emission end surface 230a in a direction (Z direction) normal to the emission end surface 230a among generatrices of the lens portion 241. The generatrix B is parallel to the X direction. When a reference plane P including the generatrix B and parallel to the lower surface 241b of the lens portion 241 is assumed, portions of the lens portion 241, each of which is included in a range of a predetermined distance L1 from the reference plane P, are symmetrical with respect to the reference plane P in a direction (Y direction) normal to the reference plane P. The predetermined distance L1 can be, for example, 0.2 mm or less.

Further, a portion of the lens portion 241 extends longer than (beyond) the predetermined distance L1 from the reference plane P in a direction opposite to the lower surface 241b. The length, in the Y direction, of the portion of the lens portion 241 extending from the reference plane P in the direction opposite to the lower surface 241b is equal to a “predetermined distance L1+distance L2 (L2>0)”. That is, the lower surface 241b of the lens portion 241 is located at the predetermined distance L1 from the reference plane P, and the upper end of the lens portion 241 is located at the “predetermined distance L1+distance L2” from the reference plane P. In the example of FIG. 10, the upper end of the lens portion 241 is a boundary between the cylindrical surface 241c of the lens portion 241 and the second surface 242b of the extension portion 242.

The lower surface 241b of the lens portion 241 is located at the predetermined distance L1 from the reference plane P. Thus, the length of the lower side of the lens portion 241 relative to the reference plane P can be reduced. Accordingly, even if the thickness of the submount 220 is reduced, the distance between the lower surface 241b of the lens portion 241 and the upper surface 210a of the base member 210 can be increased, and thus the possibility that the lower surface 241b of the lens portion 241 comes into contact with the upper surface 210a of the base member 210 can be reduced. In the light emitting device 200, a hollow gap G is present between the lower surface 241b of the lens portion 241 and the upper surface 210a of the base member 210.

Further, when a lens is molded, as the size of a lens portion 241 increases, a relative dimensional error is more likely to decrease. Therefore, when a lens having a predetermined size is manufactured, the dimensional accuracy can be improved when manufacturing a lens having a larger cylindrical surface and then cutting a portion of the lens located below the reference plane P by dicing or the like to obtain the lens 240 in which the length of a portion of the lens portion 241 extending from the reference plane P in a direction opposite to the lower surface 241b is equal to the “predetermined distance L1+distance L2”, rather than when manufacturing a lens 240x having a cylindrical surface 243c of a predetermined size. When manufacturing a lens 240, the lens 240 may be manufactured by providing a lens in which the curved shape of a cylindrical surface having a curvature is symmetrical with respect to the reference plane P for a length greater than the predetermined distance L1, and then cutting a portion of a lens portion including the cylindrical surface, which is located at a distance greater than the predetermined distance L1 from the reference plane P.

From the viewpoint of improving the heat dissipation of the light emitting device 200 and reducing the thickness of the light emitting device 200, the thickness of the submount 220, that is, a distance L3 between the upper surface and the lower surface of the submount 220 in the Y direction is preferably 250 μm or more and less than 350 μm. In this case, in the light emitting device 200, a distance L4 between the lower surface 241b of the lens portion 241 and the upper surface 210a of the base member 210 in the Y direction can be 80 μm or more. The distance L4 is more preferably 100 μm or more. By setting the distance L4 to 80 μm or more, the possibility that the lower surface 241b of the lens portion 241 comes into contact with the upper surface 210a of the base member 210 can be reduced even if a design tolerance is taken into consideration. By setting the length L4 to the above value, the lens 240 is less likely to come into contact with the base member 210 when the submount 220 with the lens 240 attached thereto is disposed on the upper surface 210a of the base member 210.

The lower surface 241b of the lens portion 241 is preferably parallel to the lower surface of the submount 220. Accordingly, the distance L4 of 80 μm or more can be easily secured when the submount 220 with the lens 240 attached thereto is disposed on the upper surface 210a of the base member 210, and also the thickness of the light emitting device 200 can be reduced. The lower surface 241b of the lens portion 241 is preferably located below the lower surface of the semiconductor laser element 230. The lower surface 241b of the lens portion 241 is preferably located below the upper surface of the submount 220. With such a configuration, light emitted from the semiconductor laser element 230 can easily reach the cylindrical surface 241c.

In FIG. 10, a region surrounded by a two-dot dash line indicates a range of the main light emitted from the semiconductor laser element 230. It is preferable that light traveling to the lowermost side, of the main light emitted from the semiconductor laser element 230, reaches the cylindrical surface 241c without being incident on the lower surface 241b of the lens portion 241. Accordingly, the main light emitted from the semiconductor laser element 230 can be extracted without leaking from the lower surface 241b of the lens portion 241. Further, of the main light emitted from the semiconductor laser element 230, light traveling to the lowermost side is preferably incident on the reflective surface 260a of the reflective member 260. This allows for increasing the amount of light reflected upward by the reflective surface 260a of the reflective member 260 of the laser light emitted from the semiconductor laser element 230, and thus the light utilization efficiency of the light emitting device 200 can be improved.

Further, an optical axis OA of the laser light emitted from the semiconductor laser element 230 is preferably included in the plane P. This allows light that is nearly parallel to the Z direction to exit from the cylindrical surface 241c of the lens portion 241. As a result, a larger portion of the main light emitted from the semiconductor laser element 230 is incident on the reflective surface 260a of the reflective member 260, and thus the light utilization efficiency of the light emitting device 200 can be improved.

### Modification

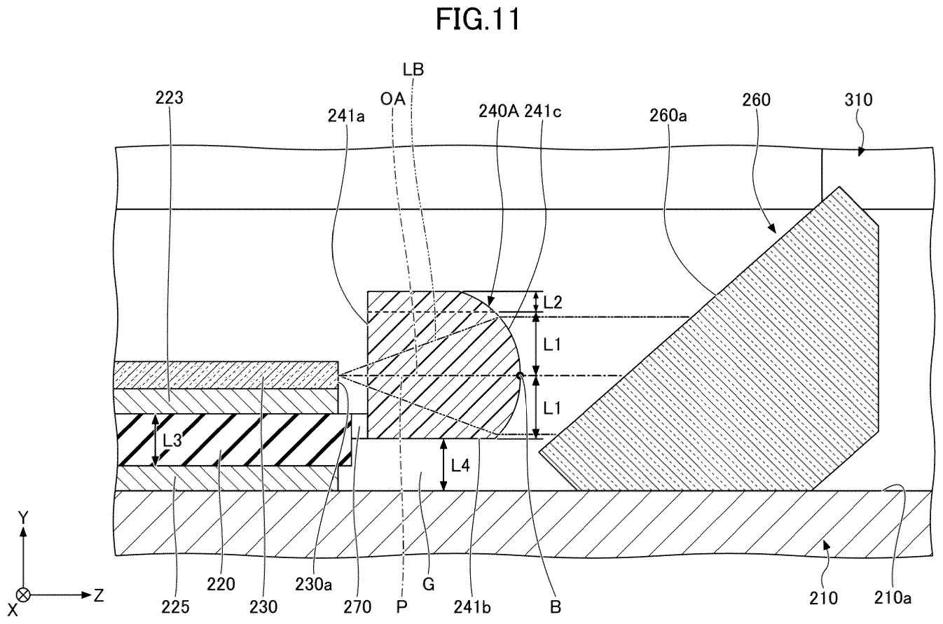

FIG. 11 is an enlarged cross-sectional view of a lens portion and the vicinity of the lens portion of a light emitting device according to a modification. The light emitting device illustrated in FIG. 11 differs from the light emitting device 200 illustrated in FIG. 1 to FIG. 8 in that the lens 240 is replaced with a lens 240A and the lens support 250 is not included.

A lens 240A is constituted only by a portion corresponding to the lens portion 241 of the lens 240, and does not include a portion corresponding to the extension portion 242. A lower portion of an incident surface 241a of the lens 240A is directly bonded to an end portion of the submount 220 via a bonding material 270.

As described above, according to the present disclosure, the lens does not necessarily include the extension portion, and may be directly fixed to the submount without using the lens support. In this case, the same effects as those of the first embodiment can be obtained.

According to one embodiment of the present disclosure, the thickness of a light emitting device can be reduced.

Although embodiments have been described in detail above, the above-described embodiments are non-limiting examples, and various modifications and substitutions can be made to the above-described embodiments without departing from the scope described in the claims.

What is claimed is:

1. A light emitting device comprising:
a base member;
a submount disposed on an upper surface of the base member;
a semiconductor laser element disposed on an upper surface of the submount and configured to emit light from an emission end surface; and
a lens directly or indirectly fixed to the submount, the lens including a lens portion having
a cylindrical surface,
an incident surface facing the emission end surface of the semiconductor laser element so that the light is to be incident on the incident surface, and
a lower surface connected to the incident surface,
when a plane that includes a generatrix of the cylindrical surface farthest from the emission end surface in a direction normal to the emission end surface among generatrices of the cylindrical surface and that is parallel to the lower surface of the lens portion is defined as a reference plane, portions of the lens portion, each of which is within a range of a predetermined distance from the reference plane in a direction normal to the reference plane, are symmetrical with respect to the reference plane, wherein
the lens portion further includes a portion that extends beyond the predetermined distance from the reference plane in the direction normal to the reference plane toward a direction opposite to the lower surface of the lens portion,
the lower surface of the lens portion is located at the predetermined distance from the reference plane, and
a gap is present between the lower surface of the lens portion and the upper surface of the base member.

2. The light emitting device according to claim 1, wherein the lower surface of the lens portion is parallel to the lower surface of the submount.

3. The light emitting device according to claim 1, wherein the light emitted from the semiconductor laser element does not exit from the lower surface of the lens portion.

4. The light emitting device according to claim 1, wherein an optical axis of the light emitted from the semiconductor laser element is included in the reference plane.

5. The light emitting device according to claim 1, wherein the lens further includes an extension portion extending from the lens portion in the direction opposite to the lower surface.

6. The light emitting device according to claim 5, further comprising
a lens support disposed on the upper surface of the submount and supporting the lens.

7. The light emitting device according to claim 6, wherein
the extension portion has a first surface continuous with the incident surface and coplanar with the incident surface, and
the first surface of the extension portion and the lens support are bonded to each other such that the lens is supported by the lens support.

8. The light emitting device according to claim 1, wherein
a distance between the upper surface and a lower surface of the submount is 250 μm or more and 350 μm or less, and
a distance between the lower surface of the lens portion and the upper surface of the base member is 80 μm or more.

9. The light emitting device according to claim 1, further comprising
a reflective member disposed on the upper surface of the base member and having a reflective surface configured to upwardly reflect the light emitted from the semiconductor laser element and passed through the lens portion.

10. The light emitting device according to claim 9, wherein an entirety of the light emitted from the semiconductor laser element and passed through the lens portion is incident on the reflective surface.

11. The light emitting device according to claim 1, wherein a lower portion of the incident surface of the lens portion is bonded to an end portion of the submount.
